(19) United States
(12) Patent Application Publication
(10) Pub. No.: US 2025/0268021 A1
(43) Pub. Date: Aug. 21, 2025

(54) DRIVE CIRCUIT SUBSTRATE AND METHOD OF MANUFACTURING DRIVE CIRCUIT SUBSTRATE

(71) Applicants: Sharp Display Technology Corporation, Kameyama City (JP); SHARP KABUSHIKI KAISHA, Sakai City (JP)

(72) Inventors: Yoshinobu NAKAMURA, Kameyama City (JP); Tadayoshi MIYAMOTO, Sakai City (JP)

(21) Appl. No.: 19/011,914

(22) Filed: Jan. 7, 2025

(30) Foreign Application Priority Data
Feb. 16, 2024 (JP) 2024-022198

(51) Int. Cl. H10K 59/121; H10K 59/12

(52) U.S. Cl. CPC H10K 59/1213; H10K 59/1201

(57) ABSTRACT

A drive circuit substrate includes a unit drive circuit including a first transistor including a first semiconductor layer having a first channel region that is a polycrystalline silicon layer, a first source region, and a first drain region, a first insulating layer that is provided on the first semiconductor layer, a first-gate-electrode-combined second facing electrode that contains a conductor impurity and an oxide semiconductor and that is provided on the first insulating layer such that the first-gate-electrode-combined second facing electrode overlaps the first channel region and a portion of the first source region that is a first facing electrode in plan view, a first drain electrode that is electrically connected to the first drain region, a first source electrode that is electrically connected to the first source region, and a holding capacitor that includes the first facing electrode and the second facing electrode.

### BACKGROUND

### 1. Field

The present disclosure relates to a drive circuit substrate and a method of manufacturing a drive circuit substrate.

### 2. Description of the Related Art

In recent years, a drive circuit substrate that includes multiple unit drive circuits including transistors has been frequently used as a pixel circuit for displaying in a display region of a display device or a drive driver that is provided in a non-display region of the display device and that drives the pixel circuit in the field of display devices. The drive circuit substrate can be used in various fields other than the field of display devices such as the fields of 3D printers and fingerprint sensors. For this reason, the research and development of these are extensively carried out.

In the description in U.S. Patent Application Publication No. 2015/0055051 and 2015/0053935, a drive circuit substrate that includes multiple unit drive circuits including a drive transistor and a selection transistor is used as a pixel circuit for displaying in a display region of a display device. However, a semiconductor layer that is included in the drive transistor or the selection transistor that is included in the unit drive circuits described in U.S. Patent Application Publication No. 2015/0055051 and 2015/0053935 is only a polycrystalline silicon layer, and a semiconductor layer that is included in the other of the drive transistor or the selection transistor is only an oxide semiconductor layer. Accordingly, the unit drive circuits described in U.S. Patent Application Publication No. 2015/0055051 and 2015/0053935 can efficiently use neither the polycrystalline silicon layer nor the oxide semiconductor layer.

It is desirable to provide a drive circuit substrate and a method of manufacturing a drive circuit substrate that efficiently use a polycrystalline silicon layer and an oxide semiconductor layer.

### SUMMARY

According to an aspect of the disclosure, there is provided a drive circuit substrate including a unit drive circuit including a first transistor including a first semiconductor layer having a first channel region that is a portion of a polycrystalline silicon layer, and a first source region and a first drain region that are formed as regions of the polycrystalline silicon layer different from the first channel region and that contain an impurity, a first insulating layer that is provided on the first semiconductor layer, a first-gate-electrode-combined second facing electrode that contains a conductor impurity and an oxide semiconductor and that is provided on the first insulating layer such that the first-gate-electrode-combined second facing electrode overlaps the first channel region and a portion of the first source region that is a first facing electrode in plan view, a first drain electrode that is electrically connected to the first drain region, a first source electrode that is electrically connected to the first source region, and a holding capacitor that includes the first facing electrode and the second facing electrode.

According to an aspect of the disclosure, there is provided a method of manufacturing a drive circuit substrate including forming a polycrystalline silicon layer, forming a first insulating layer on the polycrystalline silicon layer, forming a first channel region, a first source region that contains an impurity, and a first drain region that contains the impurity by forming a resist film that has a predetermined shape on the first insulating layer and injecting the impurity into a portion of the polycrystalline silicon layer with the resist film used as a mask, forming a first-gate-electrode-combined second facing electrode that includes a first oxide semiconductor layer and that contains a conductor impurity on the first insulating layer such that the first-gate-electrode-combined second facing electrode overlaps the first channel region and a portion of the first source region that is a first facing electrode in plan view after the resist film is removed, forming a first drain electrode that is electrically connected to the first drain region and a first source electrode that is electrically connected to the first source region, and forming a unit drive circuit including a first transistor including a holding capacitor that includes the first facing electrode and the second facing electrode.

### BRIEF DESCRIPTION OF THE DRAWINGS

FIG. 1 is a circuit diagram of one of unit drive circuits that are included in a drive circuit substrate according to a first embodiment;

FIG. 2 schematically illustrates a sectional view of the structure of a first transistor that is included in the drive circuit substrate according to the first embodiment;

FIG. 3 is a plan view of the drive circuit substrate according to the first embodiment and schematically illustrates the structure of the drive circuit substrate;

FIG. 4 schematically illustrates a sectional view of the structure of the drive circuit substrate according to the first embodiment;

FIG. 5 illustrates a comparison between the on-off characteristics of the first transistor and a second transistor that are included in the drive circuit substrate according to the first embodiment and the on-off characteristics of a transistor that includes an amorphous silicon semiconductor layer;

FIG. 6 illustrates the I-V characteristics of a second channel region in a second semiconductor layer of the second transistor that is included in the drive circuit substrate according to the first embodiment;

FIG. 7 illustrates the I-V characteristics of a first-gate-electrode-combined second facing electrode of the first transistor that is included in the drive circuit substrate according to the first embodiment and the I-V characteristics of a second source region and a second drain region in the second semiconductor layer of the second transistor;

FIG. 8 illustrates some processes in a method of manufacturing the drive circuit substrate according to the first embodiment;

FIG. 9 illustrates other processes in the method of manufacturing the drive circuit substrate according to the first embodiment;

FIG. 10 illustrates other processes in the method of manufacturing the drive circuit substrate according to the first embodiment;

FIG. 11 illustrates some processes in a method of manufacturing a drive circuit substrate in a first comparative example;

FIG. 12 schematically illustrates a sectional view of the structure of a drive circuit substrate according to a second embodiment;

FIG. 13 schematically illustrates a plan view of the structure of the drive circuit substrate in the first comparative example; and

FIG. 14 schematically illustrates a sectional view of the structure of the drive circuit substrate in the first comparative example.

### DESCRIPTION OF THE EMBODIMENTS

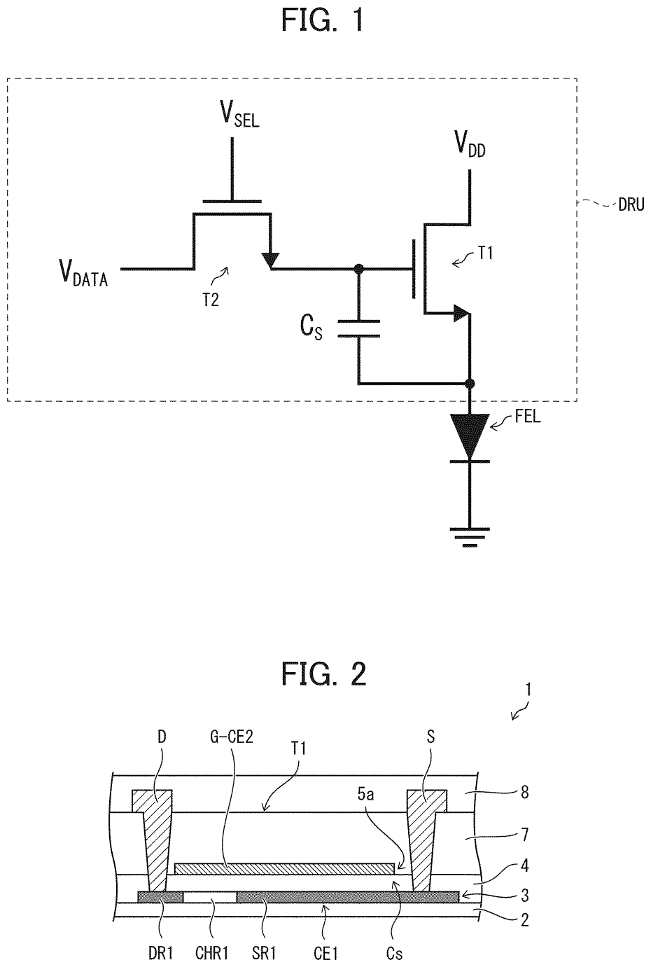

Embodiments of the present disclosure will be described below based on FIG. 1 to FIG. 14. In some cases, for convenience of description below, a component that has a function like to that of a component described according to a certain embodiment is designated by a like reference sign, and the description thereof is omitted.

### First Embodiment

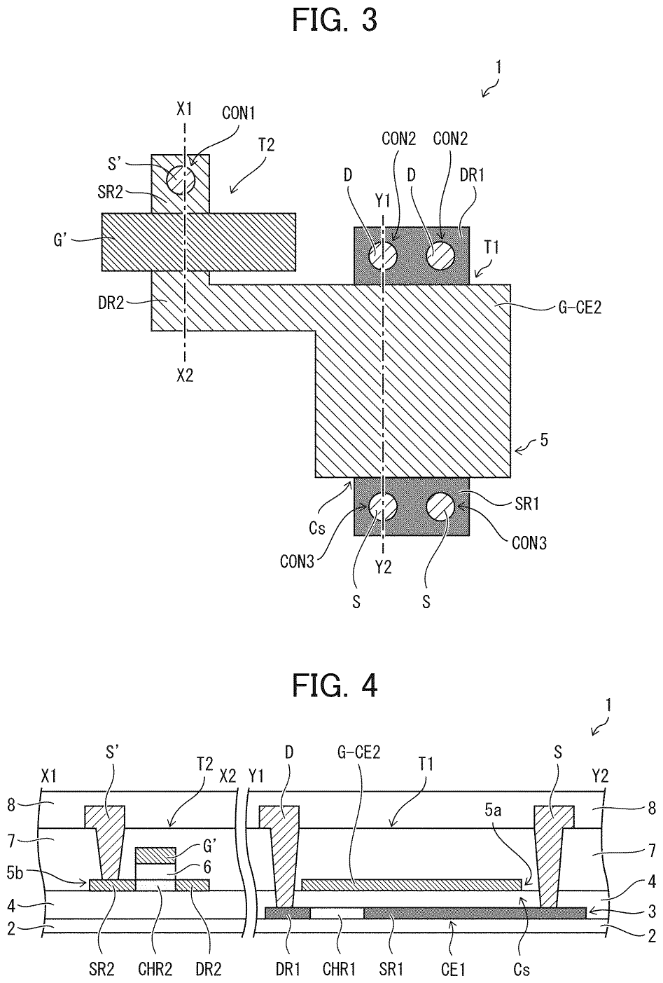

FIG. 1 is a circuit diagram of one of unit drive circuits DRU that are included in a drive circuit substrate 1 according to a first embodiment. FIG. 2 schematically illustrates a sectional view of the structure of a first transistor T1 that is included in the drive circuit substrate 1 according to the first embodiment. FIG. 3 is a plan view of the drive circuit substrate 1 according to the first embodiment and schematically illustrates the structure of the drive circuit substrate 1. In FIG. 3, a barrier layer 2, a first insulating layer 4, a second insulating layer 6, an interlayer insulating film 7, and a passivation film 8 are not illustrated. FIG. 4 schematically illustrates a sectional view of the structure of the drive circuit substrate 1 according to the first embodiment taken along a line X1-X2 and a line Y1-Y2 illustrated in FIG. 3.

In a case described by way of example according to the present embodiment, as illustrated in FIG. 1, the unit drive circuits DRU include respective light-emitting elements that serve as functional units FEL that are electrically connected to the unit drive circuits DRU. However, this is not a limitation. Fingerprint sensor units or 3D printer anode electrodes, for example, may be included as the functional units FEL that are electrically connected to the unit drive circuits DRU. For example, the unit drive circuit DRU illustrated in FIG. 1 may be a drive driver that is provided in a non-display region of a display device. In this case, the functional units FEL that are electrically connected to the unit drive circuits DRU may be pixel circuits that are provided in a display region of the display device. In a case described by way of example according to the present embodiment, the light-emitting elements that serve as the functional units FEL are organic light-emitting diodes (OLEDs). However, this is not a limitation. For example, the light-emitting elements may be quantum dot light-emitting diodes (QLEDs) or micro LEDs.

As for the unit drive circuit DRU and the functional unit FEL illustrated in FIG. 1, as illustrated in FIG. 1, FIG. 2, and FIG. 4, a first source electrode S of the first transistor T1 that is a drive transistor is electrically connected to one of electrodes of the light-emitting element that is the functional unit FEL such as an anode electrode (not illustrated) and a first facing electrode CE1 of a holding capacitor Cs. As illustrated in FIG. 1, FIG. 2, and FIG. 4, a first-gate-electrode-combined second facing electrode G-CE2 (illustrated in FIG. 2 and FIG. 4) that is a common electrode is provided as a gate electrode of the first transistor T1 and a second facing electrode of the holding capacitor Cs. As illustrated in FIG. 3, the first-gate-electrode-combined second facing electrode G-CE2 is electrically connected to a second drain region DR2 of a second transistor T2 that is a selection transistor. As illustrated in FIG. 1, a first drain electrode D of the first transistor T1 is electrically connected to a high-potential power supply voltage line VDD through which a high-potential power supply voltage is supplied, and the other electrode of the light-emitting element that is the functional unit FEL such as a cathode electrode (not illustrated) is electrically connected to a low-potential power supply voltage line through which a low-potential power supply voltage is supplied such as a low-potential power supply voltage line that is grounded. As illustrated in FIG. 1 and FIG. 4, a second source electrode

S′ of the second transistor T2 that is the selection transistor is electrically connected to a data signal line VDATA through which a data signal is supplied, and a second gate electrode G′ of the second transistor T2 is electrically connected to a scanning signal line VSEL through which a scanning signal is supplied. According to the present embodiment, as illustrated in FIG. 1, the unit drive circuits DRU include the respective light-emitting elements that are driven with an electric current and that serve as the functional units FEL that are electrically connected to the unit drive circuits DRU. Accordingly, the first transistor T1 that is included in each of the multiple unit drive circuits DRU of the drive circuit substrate 1 and that is the drive transistor may have high current drive ability. The second transistor T2 that is the selection transistor has a role in supplying a voltage corresponding to the data signal to the first transistor T1 with the timing of the scanning signal and changing the voltage of the first transistor T1, and accordingly, the second transistor T2 may have transistor characteristics such that the amount of a leak current is small. In view of this, according to the present embodiment, as illustrated in FIG. 2 and FIG. 4, the first transistor T1 that is the drive transistor includes a first semiconductor layer 3 that has a first channel region CHR1 that is a polycrystalline silicon layer, and the second transistor T2 that is the selection transistor includes a second semiconductor layer 5b that has a second channel region CHR2 that is an oxide semiconductor layer.

As illustrated in FIG. 2 and FIG. 4, the drive circuit substrate 1 includes the unit drive circuits DRU each of which includes the first transistor T1 including the first semiconductor layer 3 that has the first channel region CHR1 that is a portion of the polycrystalline silicon layer and a first source region SR1 and a first drain region DR1 that are formed as regions of the polycrystalline silicon layer different from the first channel region CHR1 and that contain impurities, the first insulating layer 4 that is provided on the first semiconductor layer 3, the first-gate-electrode-combined second facing electrode G-CE2 that is provided on the first insulating layer 4 such that the first-gate-electrode-combined second facing electrode G-CE2 overlaps the first channel region CHR1 and a portion of the first source region SR1 that is the first facing electrode CE1 in plan view and that contains conductor impurities and an oxide semiconductor, the first drain electrode D that is electrically connected to the first drain region DR1, the first source electrode S that is electrically connected to the first source region SR1, and the holding capacitor Cs that includes the first facing electrode CE1 and the second facing electrode G-CE2. In a case described by way of example according to the present embodiment, the drive circuit substrate 1 includes the unit drive circuits DRU each of which includes the first transistor T1 and the second transistor T2 but is not limited thereto, provided that the drive circuit substrate 1 includes the unit drive circuits DRU each of which includes the first transistor T1. Each first transistor T1 that is included in the drive circuit substrate 1 includes the first semiconductor layer 3 that is the polycrystalline silicon layer and the first-gate-electrode-combined second facing electrode G-CE2 that is an oxide semiconductor layer that contains the conductor impurities, and accordingly, the drive circuit substrate 1 that efficiently uses the polycrystalline silicon layer and the oxide semiconductor layer can be achieved.

As illustrated in FIG. 2 and FIG. 4, the first-gate-electrode-combined second facing electrode G-CE2 that is included in the drive circuit substrate 1 may also overlap a portion of the first drain region DR1 facing the first channel region CHR1 in plan view. With this structure, an effect of electric field relaxation can be exerted, that is, an off-current Ioff that is generated when the first transistor T1 is off can be reduced, and the first transistor T1 may not additionally include a lightly doped drain LDD between the first channel region CHR1 and the first drain region DR1 in order to exert the effect of electric field relaxation described above. This enables each unit drive circuit DRU that includes the first transistor T1 to be formed with a reduced size and enables each unit drive circuit DRU that includes the first transistor T1 to have high definition, as for the drive circuit substrate 1.

As illustrated in FIG. 3 and FIG. 4, each unit drive circuit DRU that is included in the drive circuit substrate 1 further includes the second transistor T2 in addition to the first transistor T1 described above. As illustrated in FIG. 4, the second transistor T2 includes the second semiconductor layer 5b that has the second channel region CHR2, a second source region SR2, and the second drain region DR2, the second insulating layer 6 that is provided on the second channel region CHR2 such that the second insulating layer 6 overlaps only the second channel region CHR2 in plan view, the second gate electrode G′ that is provided on the second insulating layer 6 such that the second gate electrode G′ overlaps the second channel region CHR2 in plan view, and the second source electrode S′ that is electrically connected to the second source region SR2. The second channel region CHR2 is formed in the same layer as the first-gate-electrode-combined second facing electrode G-CE2 and is composed of the same material (according to the present embodiment, an In—Ga—Zn—O semiconductor) as the oxide semiconductor that is contained in the first-gate-electrode-combined second facing electrode G-CE2. The second source region SR2 and the second drain region DR2 are formed in the same layer as the first-gate-electrode-combined second facing electrode G-CE2 and are composed of the same material (according to the present embodiment, an In—Ga—Zn—O semiconductor and conductor impurities) as the first-gate-electrode-combined second facing electrode G-CE2. That is, as illustrated in FIG. 3, the drive circuit substrate 1 includes second semiconductor layers 5 that contain an oxide semiconductor, and as illustrated in FIG. 4, the second semiconductor layers 5 include a second semiconductor layer 5a that is included in the first transistor T1 and the second semiconductor layer 5b that is included in the second transistor T2. The second semiconductor layer 5a that is included in the first transistor T1 contains conductor impurities and the oxide semiconductor and functions as the first-gate-electrode-combined second facing electrode G-CE2. The second source region SR2 and the second drain region DR2 in the second semiconductor layer 5b that is included in the second transistor T2 contain the conductor impurities and the oxide semiconductor as in the second semiconductor layer 5a that is included in the first transistor T1, and the second channel region CHR2 in the second semiconductor layer 5b that is included in the second transistor T2 is composed of the same material as the oxide semiconductor (according to the present embodiment, an In—Ga—Zn—O semiconductor) that is contained in the first-gate-electrode-combined second facing electrode G-CE2.

The second transistor T2 that is included in each unit drive circuit DRU that is included in the drive circuit substrate 1 has the second channel region CHR2 composed of the same material as the oxide semiconductor (according to the present embodiment, an In—Ga—Zn—O semiconductor) that is contained in the first-gate-electrode-combined second facing electrode G-CE2 as described above. Accordingly, the effect of electric field relaxation can be exerted, that is, the off-current Ioff that is generated when the second transistor T2 is off can be reduced, and a lightly doped drain LDD may not be additionally provided as described later. This enables each unit drive circuit DRU that includes the first transistor T1 and the second transistor T2 to be formed with a reduced size and enables each unit drive circuit DRU that includes the first transistor T1 and the second transistor T2 to have high definition, as for the drive circuit substrate 1.

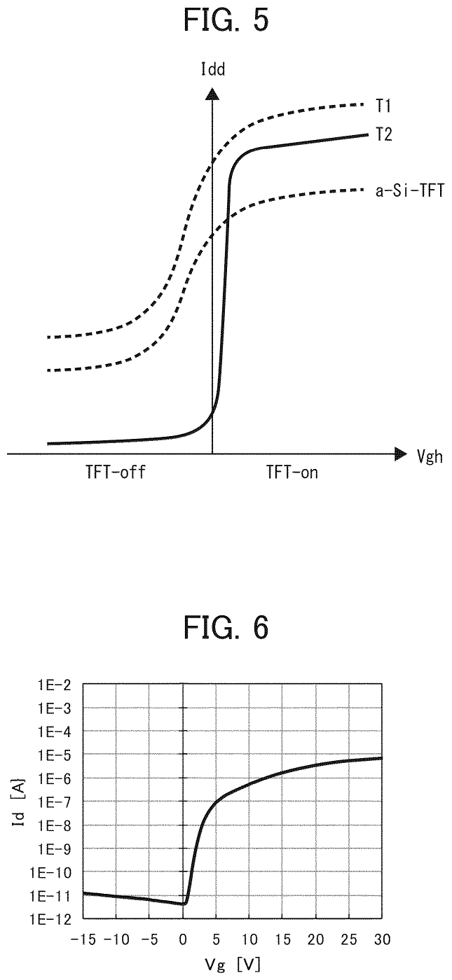

FIG. 5 illustrates a comparison between the on-off characteristics of the first transistor T1 and the second transistor T2 that are included in the drive circuit substrate 1 according to the first embodiment and the on-off characteristics of a transistor that includes an amorphous silicon semiconductor layer.

In a case described by way of example according to the present embodiment, the first channel region CHR1 that is the polycrystalline silicon layer and that the first transistor T1 that is the drive transistor has is composed of polysilicon formed at a low temperature, and the second channel region CHR2 that is the oxide semiconductor layer and that the second transistor T2 that is the selection transistor has is composed of an In—Ga—Zn—O semiconductor, but this is not a limitation. The first channel region CHR1 that is the polycrystalline silicon layer and that the first transistor T1 that is the drive transistor has may be composed of, for example, polysilicon formed at a high temperature, and the second channel region CHR2 that is the oxide semiconductor layer and that the second transistor T2 that is the selection transistor has may be composed of, for example, an oxide semiconductor other than an In—Ga—Zn—O semiconductor.

As illustrated in FIG. 5, the mobility of the first transistor T1 that is the drive transistor and that has the first channel region CHR1 that is the polycrystalline silicon layer during TFT-on, that is, the value of an electric current Idd during TFT-on is greater than the mobility of the second transistor T2 that is the selection transistor and that has the second channel region CHR2 that is the oxide semiconductor layer and a transistor in a comparative example that has a channel region that is the amorphous silicon semiconductor layer during TFT-on, that is, the value of the electric current Idd during TFT-on, and the first transistor T1 that is the drive transistor has high current drive ability.

As illustrated in FIG. 5, the mobility of the second transistor T2 that is the selection transistor and that has the second channel region CHR2 that is the oxide semiconductor layer during TFT-on, that is, the value of the electric current Idd during TFT-on is about 20 times to 50 times greater than that of the transistor in the comparative example that has the channel region that is the amorphous silicon semiconductor layer. The mobility of the second transistor T2 that is the selection transistor and that has the second channel region CHR2 that is the oxide semiconductor layer during TFT-off, that is, the value of the off-current Ioff during TFT-off is about 1/100 times that of the transistor in the comparative example that has the channel region that is the amorphous silicon semiconductor layer and is about 1/1000 times that of the first transistor T1 that is the drive transistor and that has the first channel region CHR1 that is the polycrystalline silicon layer. That is, the second transistor T2 that is the selection transistor and that has the second channel region CHR2 that is the oxide semiconductor layer when being off has a resistance value that is about 100 times that of the transistor in the comparative example that has the channel region that is the amorphous silicon semiconductor layer and that is about 1000 times that of the first transistor T1 that is the drive transistor and that has the first channel region CHR1 that is the polycrystalline silicon layer. Ion/Ioff of the second transistor T2 that is the selection transistor and that has the second channel region CHR2 that is the oxide semiconductor layer as described above, that is, the ratio between the amount of the electric current during TFT-on and the amount of the electric current during TFT-off is 109 or more, and Ion/Ioff of the first transistor T1 that is the drive transistor and that has the first channel region CHR1 that is the polycrystalline silicon layer is 107, and Ion/Ioff of the transistor in the comparative example that has the channel region that is the amorphous silicon semiconductor layer is 106. Accordingly, the second transistor T2 that is the selection transistor and that has the second channel region CHR2 that is the oxide semiconductor layer has the transistor characteristics such that the amount of a leak current is small.

As illustrated in FIG. 2 and FIG. 4, the first semiconductor layer 3 is provided on the barrier layer 2. The barrier layer 2 inhibits a foreign substance such as water or oxygen from entering the first transistor T1 and the second transistor T2 and can be composed of a silicon oxide film, a silicon nitride film, or a silicon oxynitride film that is formed by using, for example, a CVD method or a multilayer film of these. The film thickness of the barrier layer 2 is not particularly limited provided that the foreign substance such as water or oxygen can be inhibited from entering the first transistor T1 and the second transistor T2.

As illustrated in FIG. 3, the second drain region DR2 in the second transistor T2 that is included in the drive circuit substrate 1 and the first-gate-electrode-combined second facing electrode G-CE2 in the first transistor T1 may be connected to each other. With this structure, a connection contact hole for electrically connecting the second drain region DR2 that is included in the second transistor T2 and the first-gate-electrode-combined second facing electrode G-CE2 that is included in the first transistor T1 to each other may not be provided, each unit drive circuit DRU that includes the first transistor T1 and the second transistor T2 can be formed with a reduced size, and each unit drive circuit DRU that includes the first transistor T1 and the second transistor T2 can have high definition, as for the drive circuit substrate 1.

The interlayer insulating film 7 illustrated in FIG. 4 contains, for example, hydrogen that serves as conductor impurities. In the case where the interlayer insulating film 7 that contains, for example, hydrogen that is the conductor impurities is formed, the hydrogen that is the conductor impurities in the interlayer insulating film 7, for example, spreads to the second semiconductor layer 5a that is included in the first transistor T1 and that contains the oxide semiconductor in direct contact with the interlayer insulating film 7 and to the second source region SR2 and the second drain region DR2 in the second semiconductor layer 5b that is included in the second transistor T2, and the second source region SR2 and the second drain region DR2 in the second semiconductor layer 5b that is included in the second transistor T2 and the first-gate-electrode-combined second facing electrode G-CE2 that is the second semiconductor layer 5a that is included in the first transistor T1 are made conductive. Accordingly, as illustrated in FIG. 4, the interlayer insulating film 7 that contains, for example, hydrogen that is the conductor impurities may be provided on the second source region SR2, the second drain region DR2, and the first-gate-electrode-combined second facing electrode G-CE2 and may be in contact with the second source region SR2, the second drain region DR2, and the first-gate-electrode-combined second facing electrode G-CE2, and the interlayer insulating film 7 that contains, for example, hydrogen that is the conductor impurities may not be in contact with the second channel region CHR2, as for the drive circuit substrate 1. As for the drive circuit substrate 1, an interlayer insulating film that contains, for example, hydrogen that is the conductor impurities is used as the interlayer insulating film 7, the interlayer insulating film 7 is provided so as to be in direct contact with portions to be conductive in an oxide semiconductor layer as described above for making the oxide semiconductor layer conductive. Accordingly, conductor impurities may not be added into the oxide semiconductor layer.

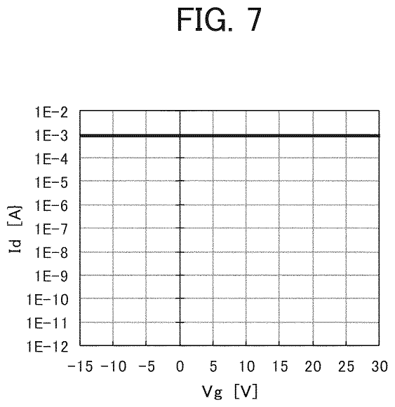

FIG. 6 illustrates the I-V characteristics of the second channel region CHR2 in the second semiconductor layer 5b of the second transistor T2 that is included in the drive circuit substrate 1 according to the first embodiment. FIG. 7 illustrates the I-V characteristics of the first-gate-electrode-combined second facing electrode G-CE2 of the first transistor T1 that is included in the drive circuit substrate 1 according to the first embodiment and the I-V characteristics of the second source region SR2 and the second drain region DR2 in the second semiconductor layer 5b of the second transistor T2.

The second insulating layer 6 illustrated in FIG. 4 may be a silicon oxide film, and the interlayer insulating film 7 that contains, for example, hydrogen that is the conductor impurities illustrated in FIG. 4 may be a single-layer film composed of silicon nitride or a multilayer film that includes a silicon nitride film that serves as a bottom layer.

As for the second semiconductor layer 5b of the second transistor T2, as illustrated in FIG. 4, the second channel region CHR2 that contains the oxide semiconductor is in contact with the second insulating layer 6 that is the silicon oxide film, and the second channel region CHR2 that contains the oxide semiconductor is oxidized by the second insulating layer 6 that is the silicon oxide film. Accordingly, as illustrated in FIG. 6, the second channel region CHR2 that contains the oxide semiconductor has resistance higher than that of the first-gate-electrode-combined second facing electrode G-CE2, the second drain region DR2, and the second source region SR2 that contain the oxide semiconductor that is made conductive.

According to the present embodiment, a multilayer film in which a lower layer is a silicon nitride film, and an upper layer is a silicon oxide film is used as the interlayer insulating film 7 that contains, for example, hydrogen that is the conductor impurities illustrated in FIG. 4. According to the present embodiment, the use of the multilayer film that includes the silicon nitride film that contains, for example, hydrogen that is the conductor impurities as the bottom layer enables the silicon nitride film that contains, for example, hydrogen that is the conductor impurities to reduce the oxide semiconductor that is contained in the second source region SR2, the second drain region DR2, and the first-gate-electrode-combined second facing electrode G-CE2 and to make the oxide semiconductor conductive. As illustrated in FIG. 7, the second source region SR2, the second drain region DR2, and the first-gate-electrode-combined second facing electrode G-CE2 that contain the conductive oxide semiconductor have resistance lower than that of the second channel region CHR2 that contains the oxide semiconductor.

In a case described by way of example according to the present embodiment, the multilayer film that includes the silicon nitride film is used as the bottom layer. However, a film other than the silicon nitride film may be used, provided that the film contains hydrogen in a predetermined amount or more and can supply hydrogen to the oxide semiconductor, that is, can reduce the oxide semiconductor. Accordingly, the interlayer insulating film 7 that contains, for example, hydrogen that is the conductor impurities illustrated in FIG. 4 may be a single-layer film composed of silicon nitride, silicon oxynitride, or silicon oxide or a multilayer film that includes two or more films among a silicon nitride film, a silicon oxynitride film, and a silicon oxide film.

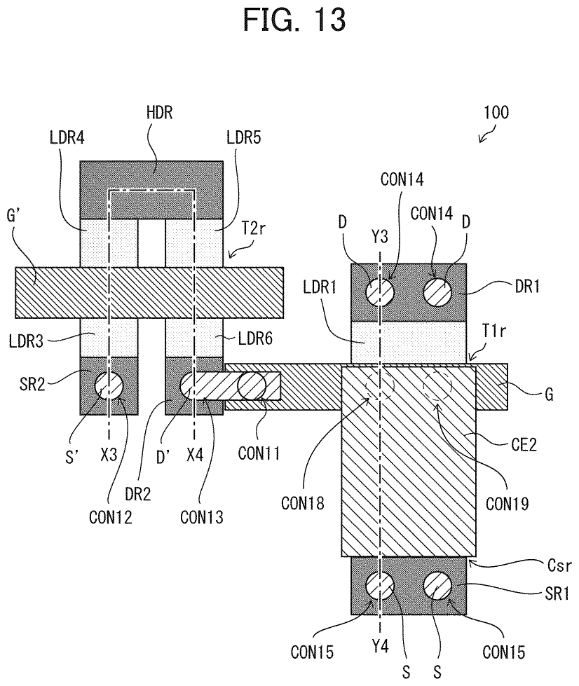

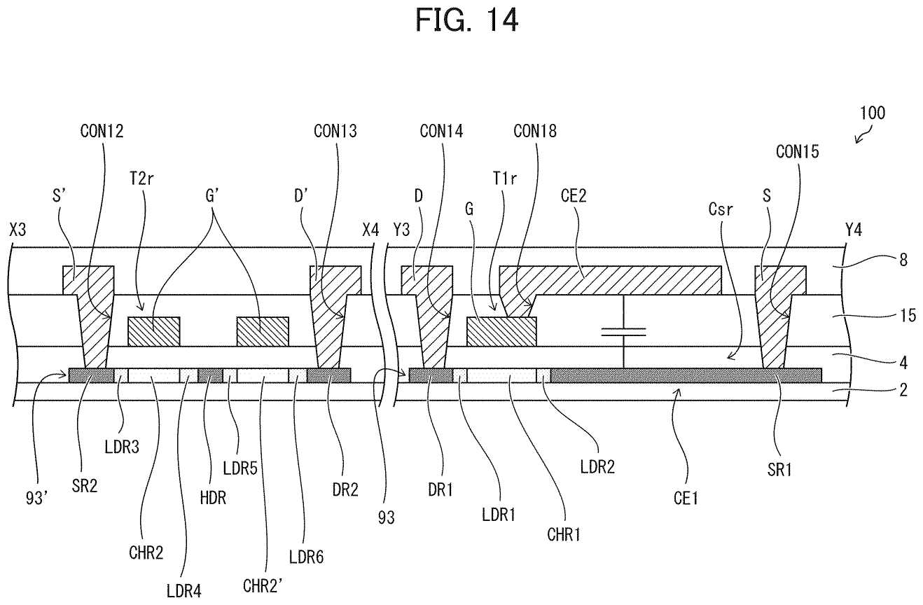

FIG. 13 schematically illustrates a plan view of the structure of a drive circuit substrate 100 in a first comparative example. In FIG. 13, the barrier layer 2, the first insulating layer 4, an interlayer insulating film 15, and the passivation film 8 are not illustrated. FIG. 14 schematically illustrates a sectional view of the structure of the drive circuit substrate 100 in the first comparative example taken along a line X3-X4 and a line Y3-Y4 illustrated in FIG. 13.

As illustrated in FIG. 13 and FIG. 14, the drive circuit substrate 100 in the first comparative example includes a unit drive circuit DRU that includes a first transistor T1r that includes a holding capacitor Csr that includes a first facing electrode CE1 and a second facing electrode CE2, and a second transistor T2r that includes a second gate electrode G′ that has a double structure. The first transistor T1r includes a first semiconductor layer 93 that has a first channel region CHR1 that is a portion of a polycrystalline silicon layer and a first source region SR1 and a first drain region DR1 that are formed as regions of the polycrystalline silicon layer different from the first channel region CHR1 and that contain impurities. Also, the second transistor T2r includes a second semiconductor layer 93′ that has second channel regions CHR2 and CHR2′ that are portions of the polycrystalline silicon layer, a second source region SR2 and a second drain region DR2 that are formed as regions of the polycrystalline silicon layer different from the second channel regions CHR2 and CHR2′ and that contain impurities, and a highly doped region HDR. The first transistor T1r includes a first drain electrode D that is electrically connected to the first drain region DR1 with a contact hole CON14 interposed therebetween and a first source electrode S that is electrically connected to the first source region SR1 with a contact hole CON15 interposed therebetween. The second transistor T2r includes a second source electrode S′ that is electrically connected to the second source region SR2 with a contact hole CON12 interposed therebetween and a second drain electrode D′ that is electrically connected to the second drain region DR2 with a contact hole CON13 interposed therebetween. In addition, the second drain region DR2 of the second transistor T2r and a first gate electrode G of the first transistor T1r are connected by the second drain electrode D′ via a contact hole CON11.

In the case of the first transistor T1r that is included in the drive circuit substrate 100 in the first comparative example, as illustrated in FIG. 13 and FIG. 14, a first gate electrode G and the second facing electrode CE2 are provided in different layers. Accordingly, as for the drive circuit substrate 100 in the first comparative example, contact holes CON18 and CON19 for electrically connecting the first gate electrode G and the second facing electrode CE2 to each other are provided in the interlayer insulating film 15. The area of the first transistor T1r that is included in the drive circuit substrate 100 in the first comparative example in which the contact holes CON18 and CON19, which may not be provided for the drive circuit substrate 1 according to the first embodiment, are provided is larger than the area of the first transistor T1 that is included in the drive circuit substrate 1 according to the first embodiment as described above For this reason, as for the drive circuit substrate 100 in the first comparative example, it is difficult for the unit drive circuit DRU to have high definition unlike the drive circuit substrate 1 according to the first embodiment.

As illustrated in FIG. 13 and FIG. 14, the first transistor T1r and the second transistor T2r that are included in the drive circuit substrate 100 in the first comparative example have the first channel region CHR1 and the second channel regions CHR2 and CHR2′ that are the polycrystalline silicon layer. Accordingly, as for the first transistor T1r, a lightly doped region LDR1 for exerting the effect of electric field relaxation is additionally provided between the first channel region CHR1 and the first drain region DR1. Similarly, as for the second transistor T2r, a lightly doped region LDR6 and a lightly doped region LDR4 for exerting the effect of electric field relaxation are additionally provided between the second channel region CHR2′ and the second drain region DR2 and between the second channel region CHR2 and the highly doped region HDR. The areas of the first transistor T1r and the second transistor T2r that are included in the drive circuit substrate 100 in the first comparative example in which a lightly doped drain LDD, which may not be provided for the drive circuit substrate 1 according to the first embodiment, is provided is larger than the areas of the first transistor T1 and the second transistor T2 that are included in the drive circuit substrate 1 according to the first embodiment. For this reason, as for the drive circuit substrate 100 in the first comparative example, it is difficult for the unit drive circuit DRU to have high definition unlike the drive circuit substrate 1 according to the first embodiment. In the case of the first transistor T1r that is included in the drive circuit substrate 100 in the first comparative example, the lightly doped region LDR1 is provided for the drain, and a lightly doped region LDR2 is provided for the source. In the case of the second transistor T2r that is included in the drive circuit substrate 100 in the first comparative example, the lightly doped regions LDR4 and LDR6 are provided for the drain, and lightly doped regions LDR3 and LDR5 are provided for the source.

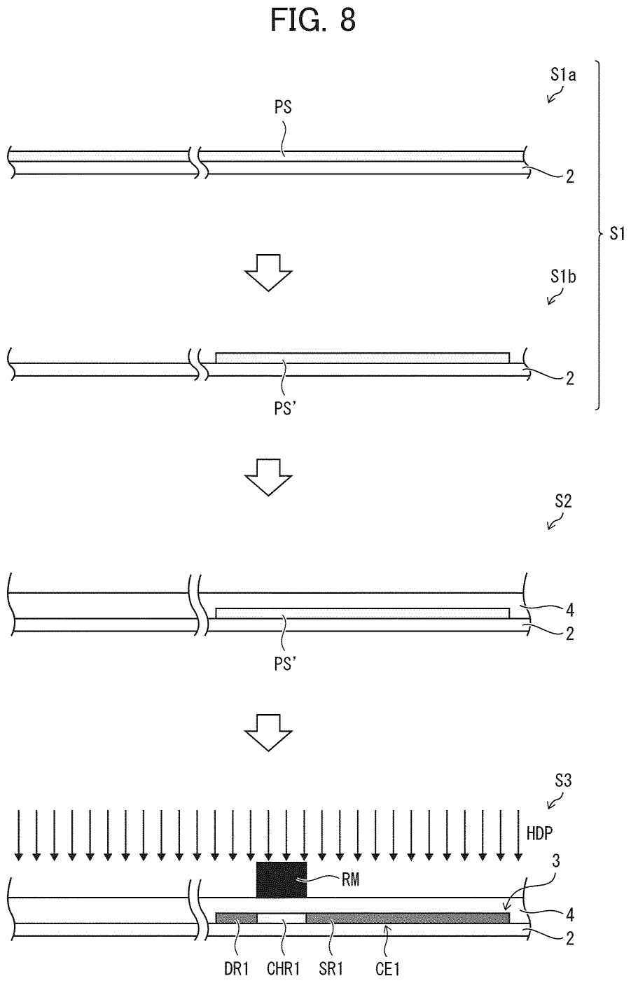

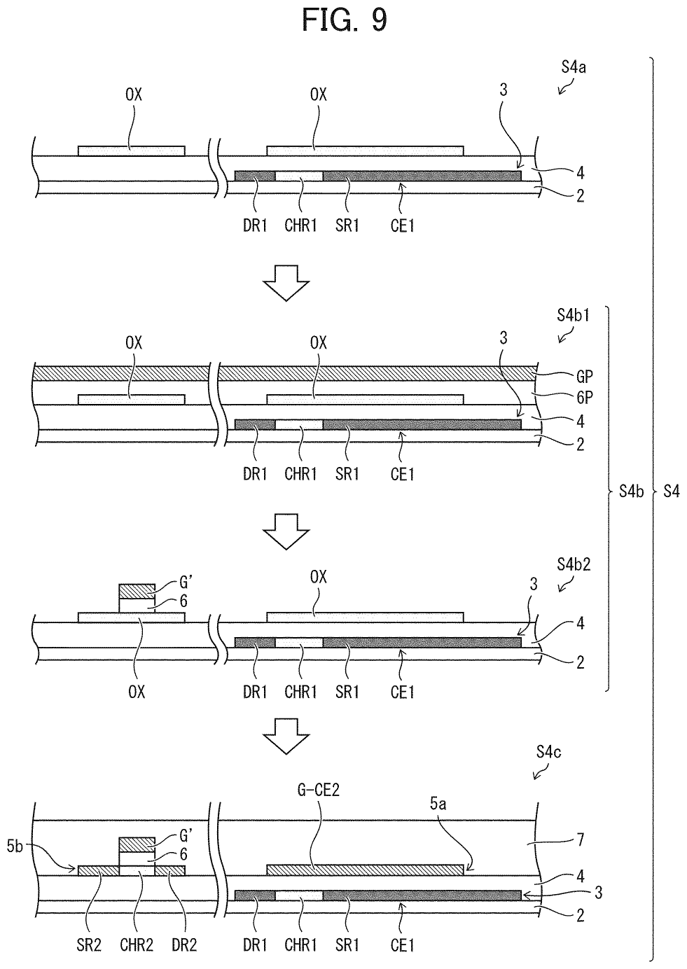

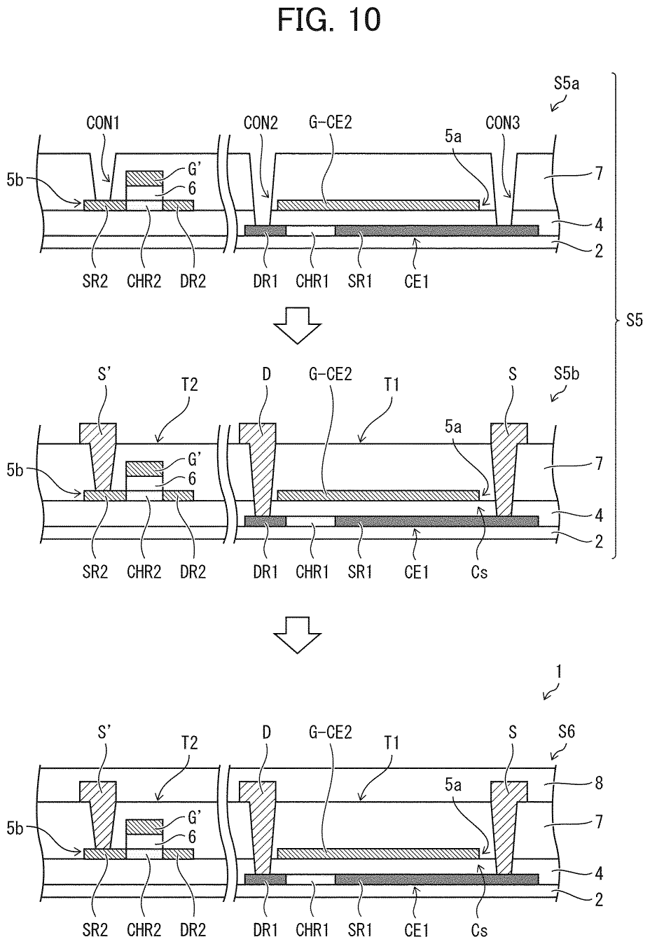

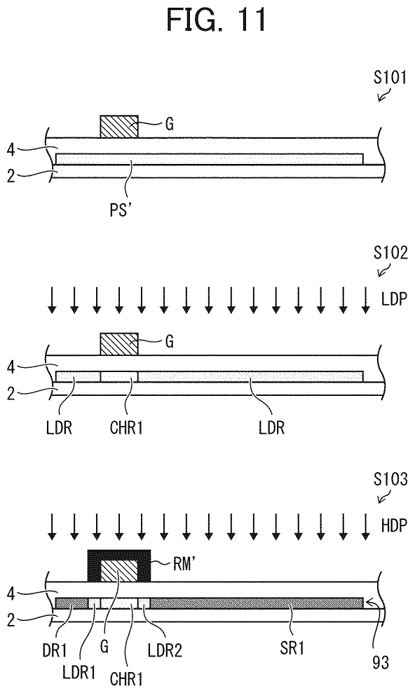

FIG. 8 illustrates some processes in a method of manufacturing the drive circuit substrate 1 according to the first embodiment. FIG. 9 illustrates other processes in the method of manufacturing the drive circuit substrate 1 according to the first embodiment. FIG. 10 illustrates other processes in the method of manufacturing the drive circuit substrate 1 according to the first embodiment. FIG. 11 illustrates some processes in a method of manufacturing the drive circuit substrate 100 in the first comparative example.

As illustrated in FIG. 8, the method of manufacturing the drive circuit substrate 1 according to the first embodiment includes a first step S1 at which a polycrystalline silicon layer PS′ is formed on the barrier layer 2, a second step S2 at which the first insulating layer 4 is formed on the polycrystalline silicon layer PS′, and a third step S3 at which a resist film RM that has a predetermined shape is formed on the first insulating layer 4, the impurities are injected into portions of the polycrystalline silicon layer PS′ with the resist film RM used as a mask, and consequently, the first semiconductor layer 3 that has the first channel region CHR1, the first source region SR1 that contains the impurities, and the first drain region DR1 that contains the impurities is formed. The first step S1 illustrated in FIG. 8 includes a step S1a at which annealing (heat treatment) for dehydrogenation is performed at, for example, about 450° C. after an amorphous silicon layer is formed on the barrier layer 2, an excimer laser process is subsequently performed at a relatively low temperature, and a polysilicon film PS that is formed at a low temperature is obtained, and a step S1b at which the polysilicon film PS is etched by using a resist film, and consequently, the polycrystalline silicon layer PS′ in the form of an island is formed on the barrier layer 2. According to the present embodiment, the polycrystalline silicon layer PS′ in the form of an island is formed with, for example, a film thickness of about 40 nm but is not limited thereto. At the second step S2 illustrated in FIG. 8, the first insulating layer 4 having a film thickness of about 85 nm can be obtained, for example, in a manner in which annealing (heat treatment) is performed after a silicon oxide film is formed. At the second step S2 illustrated in FIG. 8, the first insulating layer 4 is formed in addition to the polycrystalline silicon layer PS′ in the form of an island. At the third step S3 illustrated in FIG. 8, injection HDP of the impurities at a high concentration is performed with the resist film RM used as a mask, and consequently, the first channel region CHR1 that is protected by the resist film RM and that contains no impurities, and the first source region SR1 and the first drain region DR1 that have a higher impurities concentration than that of the first channel region CHR1 and that contain the impurities at the high concentration are formed. According to the present embodiment, the first channel region CHR1 is composed of, for example, polysilicon that is a semiconductor that contains no impurities, and the first source region SR1 and the first drain region DR1 that contain the impurities are formed in a manner in which the impurities are injected into polysilicon that is a semiconductor that contains no impurities. According to the present embodiment, the first source region SR1 and the first drain region DR1 that contain the impurities are formed in a manner in which P (phosphorus ions), which is an N-type impurity, is injected as the impurities but are not limited thereto and may be formed, for example, in a manner in which As (arsenic ions), which is an N-type impurity, is injected or B (boron ions), which is a P-type impurity, is injected.

As illustrated in FIG. 9, the method of

manufacturing the drive circuit substrate 1 according to the first embodiment further includes a fourth step S4 at which the first-gate-electrode-combined second facing electrode G-CE2 that contains a first oxide semiconductor layer OX and the conductor impurities is formed on the first insulating layer 4 so as to overlap the first channel region CHR1 and a portion of the first source region SR1 that is the first facing electrode CE1 in plan view after the resist film RM is removed. As illustrated in FIG. 10, the method of manufacturing the drive circuit substrate 1 according to the first embodiment includes a fifth step S5 at which the first drain electrode D that is electrically connected to the first drain region DR1 and the first source electrode S that is electrically connected to the first source region SR1 are formed, and is a method of forming each unit drive circuit DRU that includes the first transistor T1 that includes the holding capacitor Cs that includes the first facing electrode CE1 and the second facing electrode G-CE2. As illustrated in FIG. 10, the method of manufacturing the drive circuit substrate 1 according to the first embodiment may further include a sixth step S6 at which the passivation film 8 is formed after the fifth step S5 described above. The fourth step S4 illustrated in FIG. 9 includes an oxide semiconductor layer formation step S4a at which the first oxide semiconductor layer OX that is included in the first transistor T1 and a second oxide semiconductor layer OX that is included in the second transistor T2 are formed as the same layer on the first insulating layer 4 by using the same material, a step S4b at which the second insulating layer 6 is formed, and the second gate electrode G′ is formed on the second insulating layer 6, and a step S4c at which the interlayer insulating film 7 that contains the conductor impurities is formed. The step S4b at which the second insulating layer 6 is formed, and the second gate electrode G′ is formed on the second insulating layer 6 includes a step S4b1 at which after an inorganic film 6P a portion of which is to be the second insulating layer 6 is formed on the entire surface of the first insulating layer 4, the first oxide semiconductor layer OX, and the second oxide semiconductor layer ox, a metal film GP a portion of which is to be the second gate electrode G′ is formed on the entire surface, a second insulating layer formation step at which the second insulating layer 6 is formed so as to overlap only a portion of the second oxide semiconductor layer OX that is the second channel region CHR2 and that is included in the second transistor T2 in plan view, and a second gate electrode formation step at which the second gate electrode G′ is formed on the second insulating layer 6 so as to overlap the second channel region CHR2 in plan view. In a case described by way of example according to the present embodiment, the second insulating layer formation step at which the second insulating layer 6 is formed and the second gate electrode formation step are performed as a single step S4b2, but this is not a limitation. The second insulating layer formation step at which the second insulating layer 6 is formed and the second gate electrode formation step may be performed as different steps. According to the present embodiment, the first oxide semiconductor layer OX that is included in the first transistor T1 and the second oxide semiconductor layer OX that is included in the second transistor T2 are composed of an In—Ga—Zn—O semiconductor material with, for example, a film thickness of about 30 nm but are not limited thereto. According to the present embodiment, the second insulating layer 6 is composed of, for example, a silicon oxide film having a film thickness of about 100 nm but is not limited thereto. According to the present embodiment, the second gate electrode G′ is composed of, for example, MoW having a film thickness of about 300 nm but is not limited thereto. At the step S4c at which the interlayer insulating film 7 that contains the conductor impurities is formed illustrated in FIG. 9, the interlayer insulating film 7 that contains the conductor impurities is formed so as to be in contact with the first oxide semiconductor layer OX that is included in the first transistor T1 and the second oxide semiconductor layer OX that is included in the second transistor T2 other than the second channel region CHR2, and the second source region SR2 that contains the conductor impurities, the second drain region DR2 that contain the conductor impurities, and the first-gate-electrode-combined second facing electrode G-CE2 that contains the conductor impurities are formed. According to the present embodiment, the interlayer insulating film 7 that contains the conductor impurities is composed of a multilayer film in which a lower layer is, for example, a silicon nitride film having a film thickness of about 160 nm, and an upper layer is, for example, a silicon oxide film having a film thickness of about 680 nm but is not limited thereto.

The fifth step S5 illustrated in FIG. 10 includes a contact hole formation step S5a at which a contact hole CON1 through which the second source region SR2 of the second transistor T2 is exposed, a contact hole CON2 through which the first drain region DR1 of the first transistor T1 is exposed, and a contact hole CON3 through which the first source region SR1 of the first transistor T1 is exposed are formed. The contact hole CON1 is formed in the interlayer insulating film 7. The contact hole CON2 and the contact hole CON3 are formed in the first insulating layer 4 and the interlayer insulating film 7. The fifth step S5 illustrated in FIG. 10 further includes a step S5b at which the first drain electrode D that is electrically connected to the first drain region DR1, the first source electrode S that is electrically connected to the first source region SR1, and the second source electrode S′ that is electrically connected to the second source region SR2 are formed. According to the present embodiment, the first drain electrode D, the first source electrode S, and the second source electrode S′ are composed of, for example, a multilayer film of a Ti film having a film thickness of about 30 nm, an Al film having a film thickness of about 300 nm, and a Ti film having a film thickness of about 20 nm but are not limited thereto.

At the sixth step S6 at which the passivation film 8 is formed illustrated in FIG. 10, the passivation film 8 is composed of, for example, a silicon nitride film having a film thickness of about 300 nm but is not limited thereto.

At the fourth step S4 illustrated in FIG. 9, the first-gate-electrode-combined second facing electrode G-CE2 may be formed so as to also overlap the portion of the first drain region DR1 facing the first channel region CHR1 in plan view. Consequently, the effect of electric field relaxation can be exerted, that is, the off-current Ioff that is generated when the first transistor T1 is off can be reduced, and accordingly, the first transistor T1 may not additionally include a lightly doped drain LDD between the first channel region CHR1 and the first drain region DR1 in order to exert the effect of electric field relaxation described above. Accordingly, each unit drive circuit DRU that includes the first transistor T1 can be formed with a reduced size, and each unit drive circuit DRU that includes the first transistor T1 can have high definition, as for the drive circuit substrate 1.

At the fourth step S4 illustrated in FIG. 9, the second drain region DR2 and the first-gate-electrode-combined second facing electrode G-CE2 that are connected to each other may be formed, and at the fifth step S5 illustrated in FIG. 10, the second source electrode S′ that is electrically connected to the second source region SR2 may be formed. Consequently, a connection contact hole for electrically connecting the second drain region DR2 that the second transistor T2 has and the first-gate-electrode-combined second facing electrode G-CE2 that is included in the first transistor T1 to each other may not be provided. Accordingly, each unit drive circuit DRU that includes the first transistor T1 and the second transistor T2 can be formed with a reduced size, and each unit drive circuit DRU that includes the first transistor T1 and the second transistor T2 can have high definition, as for the drive circuit substrate 1.

At the step S4c at which the interlayer insulating film 7 that contains the conductor impurities is formed illustrated in FIG. 9, a single-layer film composed of silicon nitride, silicon oxynitride, or silicon oxide or a multilayer film that includes two or more films among a silicon nitride film, a silicon oxynitride film, and a silicon oxide film may be formed as the interlayer insulating film 7.

The second insulating layer 6 that is formed at the fourth step S4 illustrated in FIG. 9 may be composed of a silicon oxide film, and at the step S4c at which the interlayer insulating film 7 that contains the conductor impurities is formed illustrated in FIG. 9, the interlayer insulating film 7 may be composed of a single-layer film composed of silicon nitride or a multilayer film that includes a silicon nitride film that serves as a bottom layer.

In the method of manufacturing the drive circuit substrate 100 in the first comparative example illustrated in FIG. 13 and FIG. 14, as illustrated in FIG. 11, the first semiconductor layer 93 and the second semiconductor layer 93′ illustrated in FIG. 14 can be formed by performing a step S101 at which the first gate electrode G of the first transistor T1r and the second gate electrode G′ of the second transistor T2r are formed, and a step S102 at which injection LDP of impurities at a low concentration to provide a lightly doped region LDR is performed with the first gate electrode G and the second gate electrode G′ used as masks, and a step S103 at which injection HDP of impurities at a high concentration is performed with a resist film RM′ used as a mask. In the method of manufacturing the drive circuit substrate 1 according to the present embodiment, the first semiconductor layer 3 of the first transistor T1 and the second semiconductor layer 5b of the second transistor T2 can be formed by performing the third step S3 illustrated in FIG. 8, the oxide semiconductor layer formation step S4a illustrated in FIG. 9, the step S4b at which the second insulating layer 6 is formed, and the second gate electrode G′ is formed on the second insulating layer 6 illustrated in FIG. 9, and the step S4c at which the interlayer insulating film 7 that contains the conductor impurities is formed illustrated in FIG. 9. The step S4c at which the interlayer insulating film 7 that contains the conductor impurities is formed corresponds to a step at which the interlayer insulating film 15 is formed in the method of manufacturing the drive circuit substrate 100 in the first comparative example. Accordingly, as for the method of manufacturing the drive circuit substrate 1 according to the present embodiment, the steps are neither increased nor reduced in comparison with the method of manufacturing the drive circuit substrate 100 in the first comparative example, and the first semiconductor layer 3 of the first transistor T1 and the second semiconductor layer 5b of the second transistor T2 can be formed.

### Second Embodiment

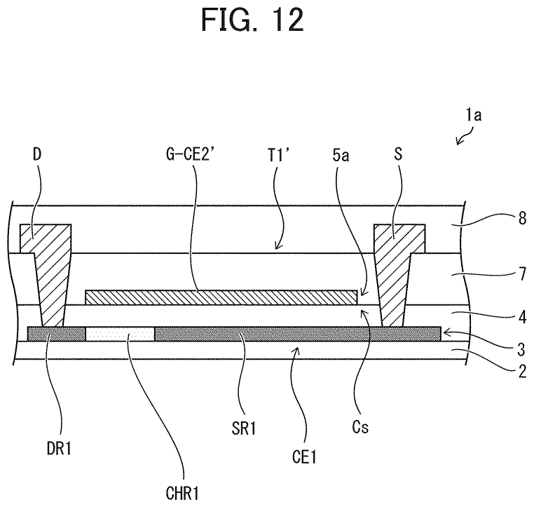

FIG. 12 schematically illustrates a sectional view of the structure of a drive circuit substrate la according to a second embodiment.

As illustrated in FIG. 12, a first-gate-electrode-combined second facing electrode G-CE2′ of a first transistor T1′ that is included in the drive circuit substrate la differs from that of the first transistor T1 that is included in the drive circuit substrate 1 according to the first embodiment described above in that the first-gate-electrode-combined second facing electrode G-CE2′ does not overlap the portion of the first drain region DR1 facing the first channel region CHR1 in plan view.

The first transistor T1′ that is included in the drive circuit substrate la includes the first semiconductor layer 3 that is the polycrystalline silicon layer and the first-gate-electrode-combined second facing electrode G-CE2′ that is the oxide semiconductor layer that contains the conductor impurities, and accordingly, the drive circuit substrate la that efficiently uses the polycrystalline silicon layer and the oxide semiconductor layer can be achieved.

The present disclosure can be used for a drive circuit substrate and a method of manufacturing a drive circuit substrate.

The present disclosure contains subject matter related to that disclosed in Japanese Priority Patent Application JP 2024-022198 filed in the Japan Patent Office on Feb. 16, 2024, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A drive circuit substrate comprising:
a unit drive circuit including a first transistor including:
a first semiconductor layer having a first channel region that is a portion of a polycrystalline silicon layer, and a first source region and a first drain region that are formed as regions of the polycrystalline silicon layer different from the first channel region and that contain an impurity;
a first insulating layer that is provided on the first semiconductor layer;
a first-gate-electrode-combined second facing electrode that contains a conductor impurity and an oxide semiconductor and that is provided on the first insulating layer such that the first-gate-electrode-combined second facing electrode overlaps the first channel region and a portion of the first source region that is a first facing electrode in plan view;
a first drain electrode that is electrically connected to the first drain region;
a first source electrode that is electrically connected to the first source region; and
a holding capacitor that includes the first facing electrode and the second facing electrode.

2. The drive circuit substrate according to claim 1,
wherein the first-gate-electrode-combined second facing electrode overlaps a portion of the first drain region facing the first channel region in plan view.

3. The drive circuit substrate according to claim 1,
wherein the unit drive circuit includes a second transistor,
wherein the second transistor includes:
a second semiconductor layer having a second channel region, a second source region, and a second drain region;
a second insulating layer that is provided on the second channel region such that the second insulating layer overlaps only the second channel region in plan view;
a second gate electrode that is provided on the second insulating layer such that the second gate electrode overlaps the second channel region in plan view; and
a second source electrode that is electrically connected to the second source region,
wherein the second channel region is formed in the same layer as the first-gate-electrode-combined second facing electrode and is composed of the same material as the oxide semiconductor, and
wherein the second source region and the second drain region are formed in the same layer as the first-gate-electrode-combined second facing electrode and are composed of the same material as the first-gate-electrode-combined second facing electrode.

4. The drive circuit substrate according to claim 3,
wherein the second drain region and the first-gate-electrode-combined second facing electrode are connected to each other.

5. The drive circuit substrate according to claim 4, further comprising:
an interlayer insulating film that contains the conductor impurity,
wherein the interlayer insulating film is provided on the second source region, the second drain region, and the first-gate-electrode-combined second facing electrode and is in contact with the second source region, the second drain region, and the first-gate-electrode-combined second facing electrode, and
wherein the interlayer insulating film is not in contact with the second channel region.

6. The drive circuit substrate according to claim 5,
wherein the interlayer insulating film is a single-layer film composed of silicon nitride, silicon oxynitride, or silicon oxide or a multilayer film that includes two or more films among a silicon nitride film, a silicon oxynitride film, and a silicon oxide film.

7. The drive circuit substrate according to claim 5,
wherein the second insulating layer is a silicon oxide film, and
wherein the interlayer insulating film is a single-layer film composed of silicon nitride or a multilayer film that includes a silicon nitride film that serves as a bottom layer.

8. A method of manufacturing a drive circuit substrate, the method comprising:
forming a polycrystalline silicon layer;
forming a first insulating layer on the polycrystalline silicon layer;
forming a first channel region, a first source region that contains an impurity, and a first drain region that contains the impurity by forming a resist film that has a predetermined shape on the first insulating layer and injecting the impurity into a portion of the polycrystalline silicon layer with the resist film used as a mask;
forming a first-gate-electrode-combined second facing electrode that includes a first oxide semiconductor layer and that contains a conductor impurity on the first insulating layer such that the first-gate-electrode-combined second facing electrode overlaps the first channel region and a portion of the first source region that is a first facing electrode in plan view after the resist film is removed;
forming a first drain electrode that is electrically connected to the first drain region and a first source electrode that is electrically connected to the first source region; and
forming a unit drive circuit including a first transistor including a holding capacitor that includes the first facing electrode and the second facing electrode.

9. The method according to claim 8,
wherein forming the first-gate-electrode-combined second facing electrode includes forming the first-gate-electrode-combined second facing electrode such that the first-gate-electrode-combined second facing electrode overlaps a portion of the first drain region facing the first channel region in plan view.

10. The method according to claim 8,
wherein forming the first insulating layer includes forming the first insulating layer on a portion other than the polycrystalline silicon layer, and
wherein forming the first-gate-electrode-combined second facing electrode includes:
forming the first oxide semiconductor layer that is included in the first transistor and a second oxide semiconductor layer that is included in a second transistor on the first insulating layer as the same layer by using the same material;
forming a second insulating layer such that the second insulating layer overlaps only a portion of the second oxide semiconductor layer that is included in the second transistor and that is a second channel region in plan view;
forming a second gate electrode on the second insulating layer such that the second gate electrode overlaps the second channel region in plan view; and
forming an interlayer insulating film that contains the conductor impurity such that the interlayer insulating film is in contact with the first oxide semiconductor layer that is included in the first transistor and the second oxide semiconductor layer that is included in the second transistor other than the second channel region and forming a second source region that contains the conductor impurity, a second drain region that contains the conductor impurity, and the first-gate-electrode-combined second facing electrode that contains the conductor impurity.

11. The method according to claim 10,
wherein forming the first-gate-electrode-combined second facing electrode includes forming the second drain region and the first-gate-electrode-combined second facing electrode that are connected to each other, and
wherein forming the first drain electrode and the first source electrode includes forming a second source electrode that is electrically connected to the second source region.

12. The method according to claim 11,
wherein forming the interlayer insulating film includes forming, as the interlayer insulating film, a single-layer film composed of silicon nitride, silicon oxynitride, or silicon oxide or a multilayer film that includes two or more films among a silicon nitride film, a silicon oxynitride film, and a silicon oxide film.

13. The method according to claim 11,
wherein forming the second insulating layer includes forming, as the second insulating layer, a silicon oxide film, and
wherein forming the interlayer insulating film includes forming, as the interlayer insulating film, a single-layer film composed of silicon nitride or a multilayer film that includes a silicon nitride film that serves as a bottom layer.
